(19) United States
(12) Patent Application Publication
(10) Pub. No.: US 2026/0198206 A1
(43) Pub. Date: Jul. 9, 2026

(54) DISPLAY PANEL AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Pingchuan ZENG, Beijing (CN); Yige QI, Beijing (CN); Ruqin ZHANG, Beijing (CN); Jinyu LI, Beijing (CN); Huan WU, Beijing (CN); Qixiao WU, Beijing (CN); Liang YAO, Beijing (CN)

(21) Appl. No.: 18/853,047

(22) PCT Filed: Jan. 23, 2024
(86) PCT No.: PCT/CN2024/073568

§ 371 Date: Sep. 30, 2024

(30) Foreign Application Priority Data
Feb. 6, 2023 (CN) 202310137855.8

(51) Int. Cl. H10K 59/80; H10K 101/20

(52) U.S. Cl. CPC H10K 59/873; H10K 59/879; H10K 2101/20

(57) ABSTRACT

Disclosed is a display panel, including a driver backplane, a first light-emitting device, an encapsulation layer, a functional layer, and a transparent filling portion. An orthographic projection of a dimming opening of the functional layer on the driving backplane covers an orthographic projection of the first light-emitting device on the driving backplane, and the transparent filling portion is disposed in the dimming opening.

The present disclosure is a U.S. national phase application based on PCT/CN2024/073568, filed on Jan. 23, 2024, which is based on and claims priority to Chinese Patent Application No. 202310137855.8, filed on Feb. 6, 2023, and entitled “DISPLAY PANEL AND DISPLAY DEVICE”, all of which are hereby incorporated by reference in their entireties for all purposes.

### TECHNICAL FIELD

The present disclosure relates to the field of display technologies, and in particular, relates to a display panel and a display device.

### BACKGROUND

Organic light emitting diodes (OLED) are known as the next generation of display devices due to their self-luminescence, high efficiency, bright colors, light weight, power saving, and rollability, and have attracted more and more attention in recent years.

### SUMMARY

Embodiments of the present disclosure provide a display panel and a display device, which can solve the problem that the display panel in the prior art has a poor display effect at a large viewing angle. The technical solutions are as follows.

In one aspect, a display panel is provided and includes:
a driver backplane;
a first light-emitting device disposed on a side of the driver backplane;
an encapsulation layer disposed on a side of the first light-emitting device away from the driver backplane;
a functional layer disposed on a side of the encapsulation layer away from the driver backplane, wherein the functional layer is provided with a dimming opening corresponding to the first light-emitting device, and an orthographic projection of the first light-emitting device on the driver backplane is disposed within an orthographic projection of the dimming opening on the driver backplane; and
a transparent filling portion at least partially disposed in the dimming opening, wherein a refractive index of the transparent filling portion is greater than a refractive index of the functional layer.

In some embodiments, an angle between an inner wall of the dimming opening and a surface of the functional layer in contact with the encapsulation layer is less than or equal to 90°.

In some embodiments, the angle between the inner wall of the dimming opening and the surface of the functional layer in contact with the encapsulation layer is greater than or equal to 50°.

In some embodiments, a shape of an orthographic projection of the dimming opening on the driver backplane is the same as a shape of an orthographic projection of the first light-emitting device on the driver backplane.

In some embodiments, the display panel further includes: a first planarization layer covering the functional layer, wherein a refractive index of the first planarization layer is greater than the refractive index of the functional layer, and a portion of the first planarization layer disposed in the dimming opening is the transparent filling portion.

In some embodiments, the transparent filling portion includes a main body portion disposed within the dimming opening, and a protrusion portion disposed outside the dimming opening, wherein an orthographic projection of the protrusion portion on the driver backplane covers an orthographic projection of the main body portion on the driver backplane, and an angle between a side surface of the protrusion portion and a surface of the protrusion portion close to the main body portion is less than or equal to 90°.

In some embodiments, a shape of a surface of the protrusion portion facing away from the main body portion is the same as a shape of an orthographic projection of the first light-emitting device on the driver backplane.

In some embodiments, angles between each side surface of the protrusion portion and a surface of the protrusion portion close to the main body portion are equal, and are greater than or equal to 50°.

In some embodiments, the display panel includes a plurality of the first light-emitting devices, the plurality of the first light-emitting devices are arranged in a plurality of columns along a first direction and in a plurality of rows along a second direction, and a maximum width of an orthographic projection of the first light-emitting device on the driver backplane in the first direction is greater than a maximum width of the orthographic projection of the first light-emitting device on the driver backplane in the second direction; and
the transparent filling portion further includes an extension portion disposed outside the dimming opening, wherein the extension portion is arranged on both sides of the protrusion portion in the second direction, and is fixedly connected to the side surface of the protrusion portion.

In some embodiments, a maximum width of an orthographic projection of the transparent filling portion on the driver backplane in the second direction is greater than or equal to a maximum width of the orthographic projection of the transparent filling portion on the driver backplane in the first direction.

In some embodiments, the display panel further includes a second planarization layer covering the transparent filling portion, wherein a refractive index of the second planarization layer is less than the refractive index of the transparent filling portion.

In some embodiments, the refractive index of the transparent filling portion is greater than a refractive index of the encapsulation layer.

In some embodiments, the first light-emitting device is a light-emitting device for emitting red light, and a light-emitting layer in the first light-emitting device contains a thermally activated delayed fluorescence (TADF) material.

In some embodiments, the display panel further includes a second light-emitting device for emitting green light, and a third light-emitting device for emitting blue light, wherein the first light-emitting device, the second light-emitting device, and the third light-emitting device are arranged in the same layer; and
the orthographic projection of the dimming opening on the driver backplane is not overlapped with an orthographic projection of the second light-emitting device on the driver backplane, and is not overlapped with an orthographic projection of the third light-emitting device on the driver backplane.

In another aspect, a display device is provided. The display device includes: a power supply assembly, and a display panel electrically connected to the power supply assembly, wherein the display panel includes the above-mentioned display panel.

The beneficial effects resulting from the technical solutions provided by the embodiments of the present disclosure include at least:

A display panel includes a driver backplane, a first light-emitting device, an encapsulation layer, a functional layer, and a transparent filling portion. The orthographic projection of the dimming opening of the functional layer on the driver backplane covers the orthographic projection of the first light-emitting device on the driver backplane, and the transparent filling portion with a higher refractive index can be distributed in the dimming opening. Therefore, the light emitted by the first light-emitting device can be directed to the transparent filling portion, and in the light entering the transparent filling portion, the light with a small viewing angle can be directly emitted after passing through the transparent filling portion, and the light with a large viewing angle can be directed to the inner wall of the dimming opening. Here, as the refractive index of the transparent filling portion is greater than the refractive index of the functional layer, and the light with a large viewing angle in the light emitted by the first light-emitting device can be totally reflected by the inner wall of the dimming opening, such that the reflected light to exit the transparent filling portion has a smaller angle with the normal of the display panel, thereby reducing the brightness of the light with a large viewing angle in the light emitted by the first light-emitting device. In this way, even if the light-emitting layer in the first light-emitting device includes the TADF material, the probability of the display screen presented by the display panel at a large viewing angle being an overall yellowish can be effectively reduced, thereby making the display effect of the display panel better.

### BRIEF DESCRIPTION OF THE DRAWINGS

To describe the technical solutions in the embodiments of the present disclosure more clearly, the following briefly introduces the accompanying drawings required for describing the embodiments. Apparently, the accompanying drawings in the following description show merely some embodiments of the present disclosure, and a person of ordinary skill in the art may still derive other drawings from these accompanying drawings without creative efforts.

FIG. 1 is a spectrum diagram of light emitted by a red light-emitting device including TADF material at different viewing angles;

FIG. 2 is a schematic diagram of a film layer structure of a display panel according to some embodiments of the present disclosure;

FIG. 3 is a light path of light emitted by a first light-emitting device in the display panel shown in FIG. 2;

FIG. 4 is a schematic diagram of a film layer structure of another display panel according to some embodiments of the present disclosure;

FIG. 5 is a top view of the display panel shown in FIG. 4;

FIG. 6 is a top view of a display panel according to other embodiments of the present disclosure;

FIG. 7 is a schematic diagram of a film layer structure of the display panel at position A-A′ shown in FIG. 6;

FIG. 8 is a schematic diagram of a film layer structure of the display panel at position B-B′ shown in FIG. 6;

FIG. 9 is a CIE trajectory comparison diagram and white light color deviation degree comparison diagram in a short side direction when a display panel provided by the present disclosure and a display panel in the related art present a white picture;

FIG. 10 is a CIE trajectory comparison diagram and white light color deviation degree comparison diagram in a long side direction when a display panel provided by the present disclosure and a display panel in the related art present a white picture;

FIG. 11 is a top view of another display panel according to other embodiments of the present disclosure;

FIG. 12 is a schematic diagram of a film layer structure of the display panel at position A-A′ shown in FIG. 11;

FIG. 13 is a schematic diagram of a film layer structure of the display panel at position B-B′ shown in FIG. 11;

FIG. 14 is a schematic diagram of a three-dimensional structure of a protrusion portion according to some embodiments of the present disclosure;

FIG. 15 is another CIE trajectory comparison diagram and a white light color deviation degree comparison diagram in a short side direction when a display panel provided by the present disclosure and a display panel in the related art present a white picture;

FIG. 16 is another CIE trajectory comparison diagram and a white light color deviation degree comparison diagram in a long side direction when a display panel provided by the present disclosure and a display panel in the related art present a white picture;

FIG. 17 is a top view of yet another display panel according to other embodiments of the present disclosure;

FIG. 18 is a schematic diagram of a film layer structure of the display panel at position A-A′ shown in FIG. 17;

FIG. 19 is a schematic diagram of a film layer structure of the display panel at position B-B′ shown in FIG. 17;

FIG. 20 is a schematic diagram of a three-dimensional structure of a portion of a transparent filling portion disposed outside a dimming opening according to some embodiments of the present disclosure;

FIG. 21 is another CIE trajectory comparison diagram and white light color deviation degree comparison diagram in a short side direction when a display panel provided by the present disclosure and a display panel in the related art present a white picture;

FIG. 22 is another CIE trajectory comparison diagram and white light color deviation degree comparison diagram in a long side direction when a display panel provided by the present disclosure and a display panel in the related art present a white picture;

FIG. 23 is a schematic diagram of a film layer structure of a display panel according to yet other embodiments of the present disclosure; and

FIG. 24 is a schematic diagram of a film layer structure of a display panel according to yet other embodiments of the present disclosure.

### DETAILED DESCRIPTION

For clearer descriptions of the objectives, technical solutions, and advantages of the present disclosure, embodiments of the present disclosure are described in detail hereinafter with reference to the accompanying drawings.

At present, in order to meet the demand for a high color gamut of display panels, it is necessary to set a thermally activated delayed fluorescence (TADF) material in the light-emitting layer of the OLED light-emitting device.

For example, a TADF material is usually provided in the light-emitting layer of a red light-emitting device used to emit red light in a display panel. However, due to the limitations of the TADF material itself, the brightness of the light emitted by the red light-emitting device at a large viewing angle (i.e., an angle between the emission direction and the normal of the display panel is large) decays slowly, resulting in the display screen presented by the display panel at a large viewing angle having an overall yellowish undesirable phenomenon, which in turn results in a poor display effect of the display screen presented by the display panel at a large viewing angle.

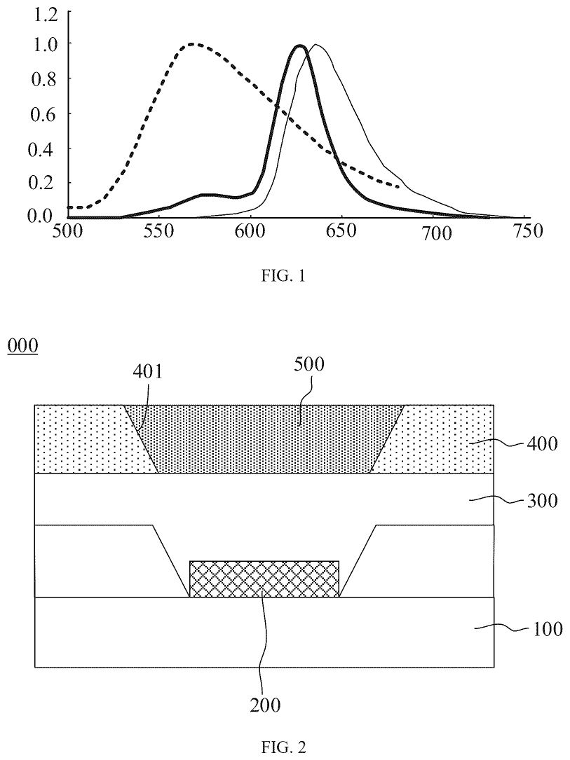

For example, referring to FIG. 1, FIG. 1 is a spectrum diagram of light emitted by a red light-emitting device including TADF material at different viewing angles. In FIG. 1, the thick solid line represents the spectrum of the light emitted by the red light-emitting device with an angle of 60° between the emission direction and the normal of the display panel, that is, the spectrum of light at a large viewing angle in the light emitted by the red light-emitting device; the thin solid line represents the spectrum of light emitted by the red light-emitting device with an angle of 0° between the emission direction and the normal of the display panel; the thick dotted line represents the intrinsic spectrum of the TADF material. For the spectrum of light emitted by the red light-emitting device with an angle of 60° between the emission direction and the normal of the display panel, there is a new peak at 570 nm, and the peak of the TADF intrinsic spectrum is also at 570 nm. For this reason, the brightness of the light emitted by the red light-emitting device with an angle of 60° between the emission direction and the normal of the display panel decays more slowly.

Referring to FIG. 2, FIG. 2 is a schematic diagram of a film structure of a display panel according to some embodiments of the present disclosure. The display panel 000 may include a driver backplane 100, a first light-emitting device 200, an encapsulation layer 300, a functional layer 400, and a transparent filling portion 500.

The first light-emitting device 200 in the display panel 000 may be disposed on the side of the driver backplane 100. Here, the first light-emitting device 200 may be electrically connected to the driver backplane 100, and the driver backplane 100 may drive the first light-emitting device to emit light.

The encapsulation layer 300 in the display panel 000 is disposed on the side of the first light-emitting device 200 away from the driver backplane 100. Here, the encapsulation layer 300 is configured to encapsulate the first light-emitting device 200 to prevent erosion of the light-emitting layer in the first light-emitting device 200 by water and oxygen in the external environment, thereby ensuring a longer service life of the first light-emitting device 200.

The functional layer 400 in the display panel 000 is disposed on a side of the encapsulation layer 300 away from the driver backplane 100, and the functional layer 400 may be provided with a dimming opening 401 corresponding to the first light-emitting device 200. Here, an orthographic projection of the first light-emitting device 200 on the driver backplane 100 may be disposed within an orthographic projection of the dimming opening 401 in the functional layer 400 on the driver backplane 100. It should be noted that the display panel 000 usually includes a plurality of first light-emitting devices 200 arranged in an array, and thus the functional layer 400 also needs to be provided with a plurality of dimming openings 401 corresponding to the plurality of first light-emitting devices 200 one by one, and the orthographic projection of each first light-emitting device 200 on the driver backplane 100 may be disposed within the orthographic projection of the corresponding dimming opening 401 on the driver backplane 100.

At least a portion of the transparent filling portion 500 in the display panel 000 may be disposed in the dimming opening 401, and the refractive index of the transparent filling portion 500 may be greater than the refractive index of the functional layer 400.

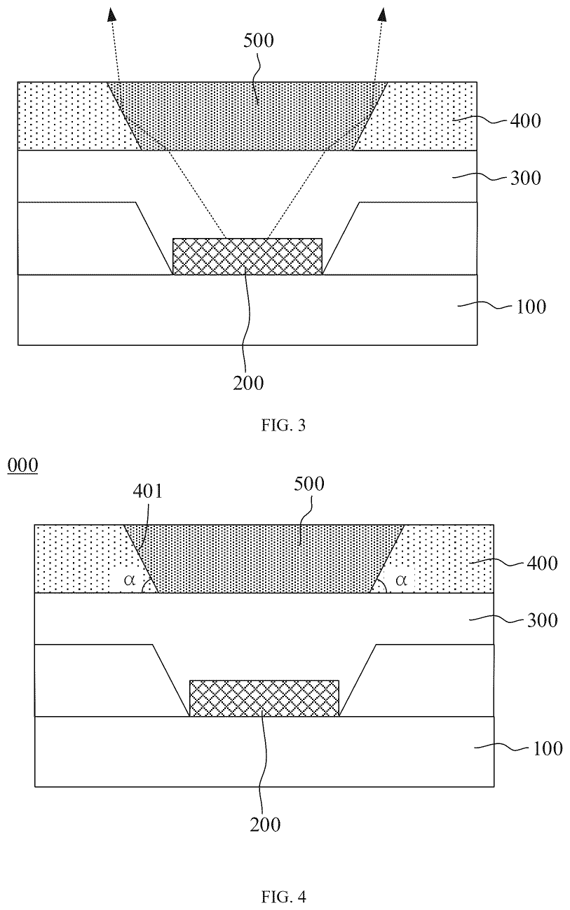

In the embodiments of the present disclosure, the orthographic projection of the dimming opening 401 of the functional layer 400 on the driver backplane 100 covers the orthographic projection of the first light-emitting device 200 on the driver backplane 100, and the transparent filling portion 500 with a higher refractive index can be distributed in the dimming opening 401. Therefore, the light emitted by the first light-emitting device 200 can be directed to the transparent filling portion 500. As shown in FIG. 3, FIG. 3 is a light path of light emitted by a first light-emitting device in the display panel shown in FIG. 2. In the light entering the transparent filling portion 500, the light with a small viewing angle (that is, the angle between the emission direction and the normal of the display panel is small) can be directly emitted after passing through the transparent filling portion 500, and the light with a large viewing angle (that is, the angle between the emission direction and the normal of the display panel is large) can be emitted to the inner wall of the dimming opening 401. Here, as the refractive index of the transparent filling portion 500 is greater than the refractive index of the functional layer 400, the light with a large viewing angle in the light emitted by the first light-emitting device 200 can be totally reflected by the inner wall of the dimming opening 401, such that the reflected light has a smaller angle with the normal of the display panel when it is emitted from the transparent filling portion 500, thereby making the brightness of the light with a large viewing angle in the light emitted by the first light-emitting device 200 lower.

In a possible implementation, the first light-emitting device 200 may be a light-emitting device for emitting red light, and the light-emitting layer in the first light-emitting device 200 includes a TADF material. In this case, even if the light-emitting layer in the first light-emitting device 200 includes the TADF material, the probability that the display screen presented by the display panel 000 at a large viewing angle appears an overall yellowish can be effectively reduced, thereby making the display effect of the display panel 000 better.

In another possible implementation, the first light-emitting device 200 may also be a light-emitting device for emitting light of other colors (for example, green light or blue light). In this way, when the brightness of the light at a large viewing angle emitted by the light-emitting device for emitting light of other colors decays slowly, the dimming opening 401 of the functional layer 400 and the transparent filling portion 500 filled in the dimming opening 401 can also reduce the brightness of the light at a large viewing angle in the light emitted by the light-emitting device, such that the color of the display screen presented by the display panel at a large viewing angle is calibrated.

In summary, the display panel provided by the embodiments of the present disclosure includes a driver backplane, a first light-emitting device, an encapsulation layer, a functional layer, and a transparent filling portion. The orthographic projection of the dimming opening of the functional layer on the driver backplane covers the orthographic projection of the first light-emitting device on the driver backplane, and the transparent filling portion with a higher refractive index can be distributed in the dimming opening. Therefore, the light emitted by the first light-emitting device can be directed to the transparent filling portion, and in the light entering the transparent filling portion, the light with a small viewing angle can be directly emitted after passing through the transparent filling portion, and the light with a large viewing angle can be directed to the inner wall of the dimming opening. Here, since the refractive index of the transparent filling portion is greater than the refractive index of the functional layer, the light with a large viewing angle in the light emitted by the first light-emitting device can be totally reflected by the inner wall of the dimming opening, such that the reflected light to exit the transparent filling portion has a smaller angle with the normal of the display panel, thereby reducing the brightness of the light with a large viewing angle in the light emitted by the first light-emitting device. In this way, even if the light-emitting layer in the first light-emitting device includes the TADF material, the probability of the display screen presented by the display panel at a large viewing angle being an overall yellowish can be effectively reduced, thereby making the display effect of the display panel better.

In the present disclosure, referring to FIG. 4, FIG. 4 is a schematic diagram of a film layer structure of another display panel according to some embodiments of the present disclosure. The angle a between the inner wall of the dimming opening 401 of the functional layer 400 in the display panel 000 and the surface of the functional layer 400 in contact with the encapsulation layer 300 is less than or equal to 90°. That is, the inner wall of the dimming opening 401 can be a plane that is substantially perpendicular to the surface of the encapsulation layer 300 that faces away from the driver backplane 100, or the inner wall of the dimming opening 401 can also be an inclined surface, and the angle between the inclined surface and the surface of the functional layer 400 in contact with the encapsulation layer 300 is an acute angle.

In this case, the light with a large viewing angle in the light emitted by the first light-emitting device 200 is directed toward the inner wall of the dimming opening 401 and is reflected by the inner wall of the dimming opening 401. The reflected light can be emitted from the side of the transparent filling portion 500 away from the driver backplane 100. In this way, the light-emitting efficiency of the first light-emitting device 200 can be ensured to be high while ensuring that the brightness of the light with a large viewing angle in the light emitted by the first light-emitting device 200 is low.

In some embodiments, the angle a between the inner wall of the dimming opening 401 of the functional layer 400 in the display panel 000 and the surface of the functional layer 400 in contact with the encapsulation layer 300 is greater than or equal to 50°. In this way, the inner wall of the dimming opening 401 can better reflect the light with a large viewing angle in the light emitted by the first light-emitting device 200.

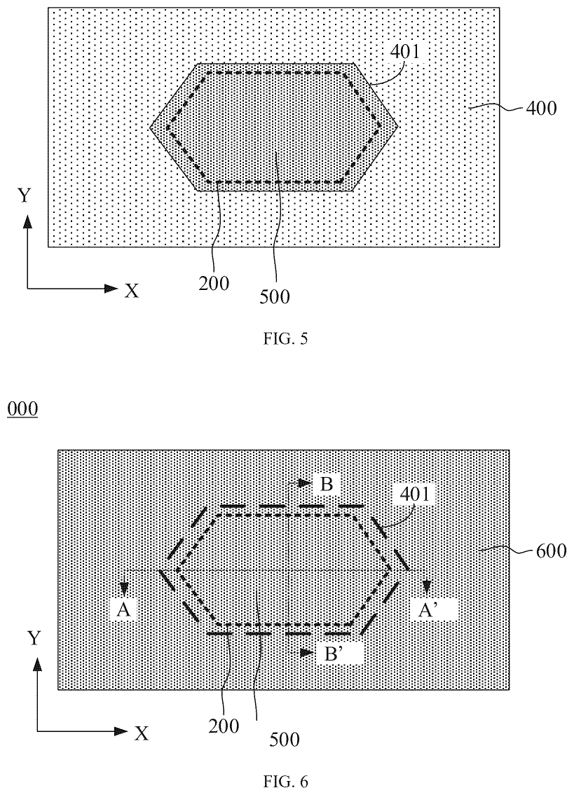

In the embodiments of the present disclosure, as shown in FIG. 5, FIG. 5 is a top view of the display panel shown in FIG. 4. The shape of the orthographic projection of the dimming opening 401 of the functional layer 400 on the driver backplane 100 is the same as the shape of the orthographic projection of the first light-emitting device 200 on the driver backplane 100. For example, when the shape of the orthographic projection of the first light-emitting device 200 on the driver backplane 100 is a hexagon, the orthographic projection of the dimming opening 401 on the driver backplane 100 is also a hexagon. In this way, it can be ensured that the light with a large viewing angle emitted from each side of the first light-emitting device 200 can be emitted to the corresponding inner wall of the dimming opening 401, such that the inner wall of the dimming opening 401 can better reflect the light with a large viewing angle emitted by the first light-emitting device 200.

It should be noted that when the shape of the orthographic projection of the first light-emitting device 200 on the driver backplane 100 is a hexagon, the hexagon may generally be a flat hexagon. For example, as shown in FIG. 5, the plurality of first light-emitting devices 200 in the display panel 000 may generally be arranged in a plurality of columns along a first direction X, and in a plurality of rows along a second direction Y. The maximum width of the orthographic projection of the first light-emitting device 200 on the driver backplane 100 in the first direction X is greater than the maximum width of the orthographic projection of the first light-emitting device 200 on the driver backplane 100 in the second direction Y. For this reason, the first direction X is the long side direction of the first light-emitting device 200, and the second direction Y is the short side direction of the first light-emitting device 200. In addition, the maximum width of the orthographic projection of a device on the driver backplane 100 in the present disclosure in a certain direction (e.g., the first direction) refers to the distance between the two boundary points of the outer boundary of the orthographic projection of the device on the driver backplane that are separated by a maximum in the certain direction.

It should also be noted that each of the first light-emitting devices 200 in the display panel 000 can be a light-emitting device for emitting red light; or, each of the first light-emitting devices 200 in the display panel 000 can be a light-emitting device for emitting green light or a light-emitting device for emitting blue light; or, the plurality of first light-emitting devices 200 in the display panel 000 can include at least two types of light-emitting devices, wherein the at least two types of light-emitting devices can be a light-emitting device for emitting red light, a light-emitting device for emitting green light, and a light-emitting device for emitting blue light. For this reason, the embodiments of the present disclosure do not specifically limit the type of the first light-emitting device 200, and the first light-emitting device 200 belongs to any type of light-emitting device that needs to reduce the brightness of the light with a large viewing angle.

In the present disclosure, in the case that each of the first light-emitting devices 200 in the display panel 000 is a light-emitting device for emitting red light, in addition to the first light-emitting device 200 for emitting red light, referring to FIG. 24, FIG. 24 is a schematic diagram of a film layer structure of a display panel according to yet other embodiments of the present disclosure, the display panel 000 generally also includes a second light-emitting device 900 for emitting green light, and a third light-emitting device 1000 for emitting blue light. Here, the first light-emitting device 200, the second light-emitting device, and the third light-emitting device in the display panel 000 can be arranged in the same layer. In this way, the red light emitted by the first light-emitting device 200, the green light emitted by the second light-emitting device, and the blue light emitted by the third light-emitting device can make the display panel 000 appear as a colorful display panel. It should be noted that the structure of the first light-emitting device 200 can be similar to that of the second light-emitting device, and can be similar to that of the third light-emitting device. The three light-emitting devices are only different in the material of the light-emitting layer.

The orthographic projection of the dimming opening 401 of the functional layer 400 on the driver backplane 100 is not overlapped with the orthographic projection of the second light-emitting device on the driver backplane 100, and is not overlapped with the orthographic projection of the third light-emitting device on the driver backplane 100. Here, as the brightness attenuation of the light with a large viewing angle in the light emitted by the second light-emitting device and the third light-emitting device is usually within the normal range, it is not necessary to adjust the light with a large viewing angle in the light emitted by the second light-emitting device and the third light-emitting device through the dimming opening 401 of the functional layer 400, such that the light with a large viewing angle in the light emitted by the second light-emitting device and the third light-emitting device can still be emitted normally. For this reason, the dimming opening 401 of the functional layer 400 can only reduce the brightness of the light with a large viewing angle in the light emitted by the first light-emitting device 200, and the dimming opening 401 can not affect the brightness of the light with a large viewing angle in the light emitted by the second light-emitting device and the third light-emitting device. In this way, not only can it reduce the probability of the image presented by the display panel 000 at a large viewing angle being yellowish, but it can also ensure that the display panel 000 can normally present a colorful image at a large viewing angle.

It should be noted that there are various structures of the transparent filling portion 500 in the dimming opening 401 of the functional layer 400. The embodiments of the present disclosure are schematically described by taking the following three optional implementations as examples.

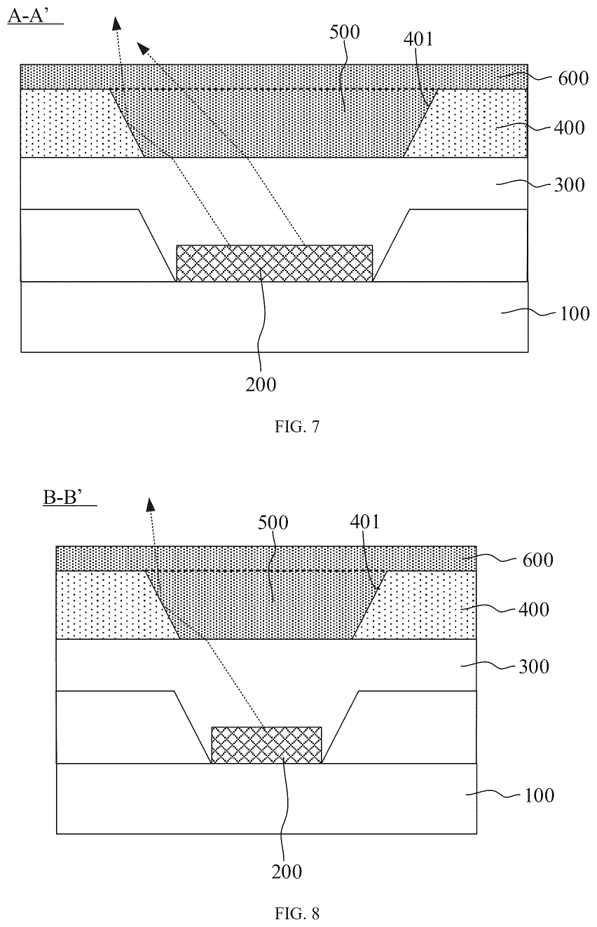

In a first optional implementation, as shown in FIG. 6, FIG. 7, and FIG. 8, FIG. 6 is a top view of a display panel according to other embodiments of the present disclosure, FIG. 7 is a schematic diagram of a film structure of the display panel at position A-A′ shown in FIG. 6, and FIG. 8 is a schematic diagram of a film structure of the display panel at position B-B′ shown in FIG. 6. As the maximum width of the orthographic projection of the first light-emitting device 200 on the driver backplane 100 in the first direction X is greater than the maximum width of the orthographic projection of the first light-emitting device 200 on the driver backplane 100 in the second direction Y. Therefore, FIG. 7 can be a cross-sectional view of the first light-emitting device 200 in the long side direction, and FIG. 8 is a cross-sectional view of the first light-emitting device 200 in the short side direction.

The display panel 000 may further include a first planarization layer 600 covering the functional layer 400. The refractive index of the first planarization layer 600 is greater than the refractive index of the functional layer 400. For example, the first planarization layer 600 may be disposed on the side of the functional layer 400 away from the driver backplane 100, and the orthographic projection of the functional layer 400 on the driver backplane 100 is disposed within the orthographic projection of the first planarization layer 600 on the driver backplane. In this case, a portion of the first planarization layer 600 may be filled in the dimming opening 401, and for this purpose, the portion of the first planarization layer 600 disposed in the dimming opening is the transparent filling portion 500 in the display substrate 000.

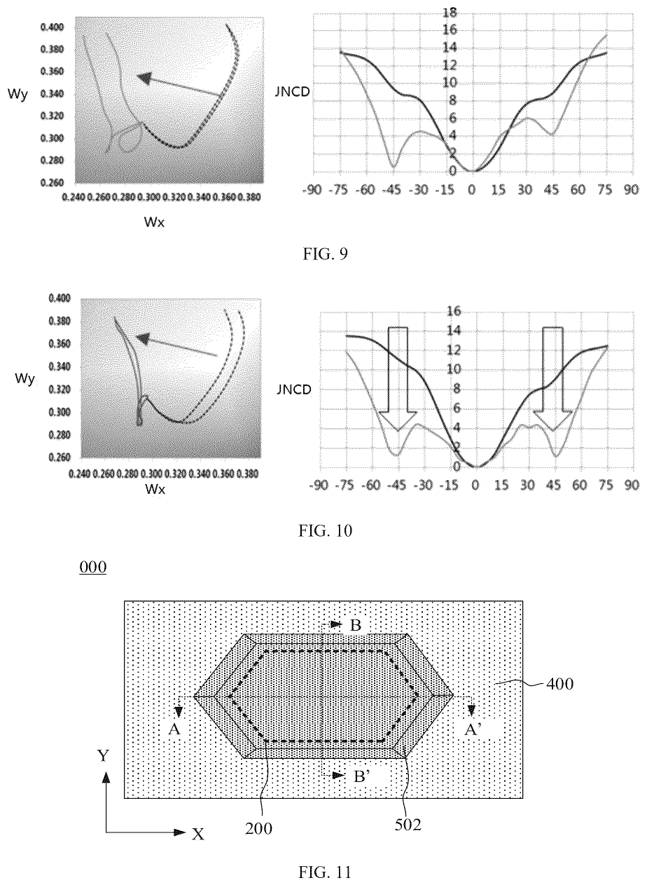

For example, referring to FIG. 9 and FIG. 10. FIG. 9 is a CIE trajectory comparison diagram and white light color deviation degree comparison diagram in a short side direction when a display panel provided by the present disclosure and a display panel in the related art present a white picture. FIG. 10 is a CIE trajectory comparison diagram and white light color deviation degree comparison diagram in the long side direction when the display panel provided by the present disclosure and a display panel in the related art present a white picture. The CIE trajectory can be used to represent the color shift trajectory of the display panel in the color gamut diagram when the display panel displays a white picture, and the horizontal coordinate Wx and the vertical coordinate Wy represent the chromaticity value respectively. The schematic diagram of the white light color deviation degree can be used to represent the color shift curve of the display panel when displaying a white picture. The horizontal coordinate of the color shift curve represents the viewing angle of the display panel, the vertical coordinate represents the color shift value, and the unit is JNCD. In the CIE trajectory comparison diagrams of FIG. 9 and FIG. 10, the solid line represents the CIE trajectory when the display panel 000 provided in the embodiments of the present disclosure presents a white picture, the dotted line represents the CIE trajectory when the display panel in the related art presents a white picture, and the arrow represents the direction of change of the CIE trajectory; in the white light color deviation degree comparison diagrams of FIG. 9 and FIG. 10, the thin solid line represents the color deviation curve when the display panel 000 provided in the embodiment of the present disclosure presents a white picture, and the thick solid line represents the color deviation curve when the display panel in the related art presents a white picture. It can be seen from FIG. 9 and FIG. 10 that the picture presented by the display panel in the related art will be yellow at a large viewing angle, while the display panel in the present disclosure can effectively improve the phenomenon of picture luminescence at a large viewing angle. In addition, the display panel provided by the embodiments of the present disclosure has a white light large viewing angle color deviation (JNCD) value that is greatly reduced relative to the display panel in the related art, such that the color accuracy of the display panel provided by the embodiments of the present disclosure is higher.

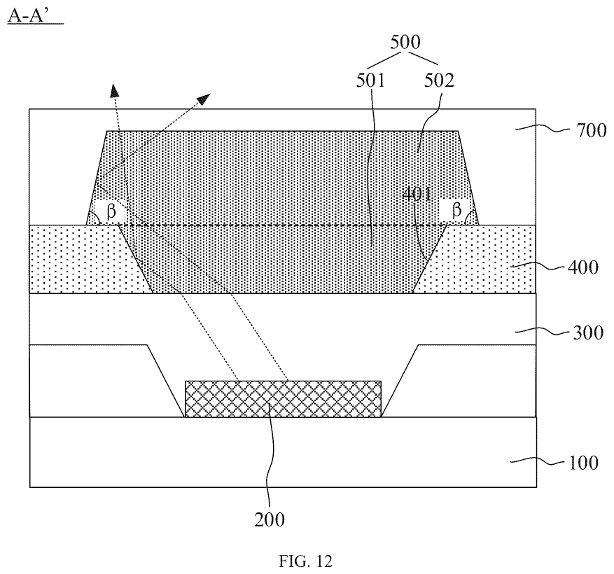

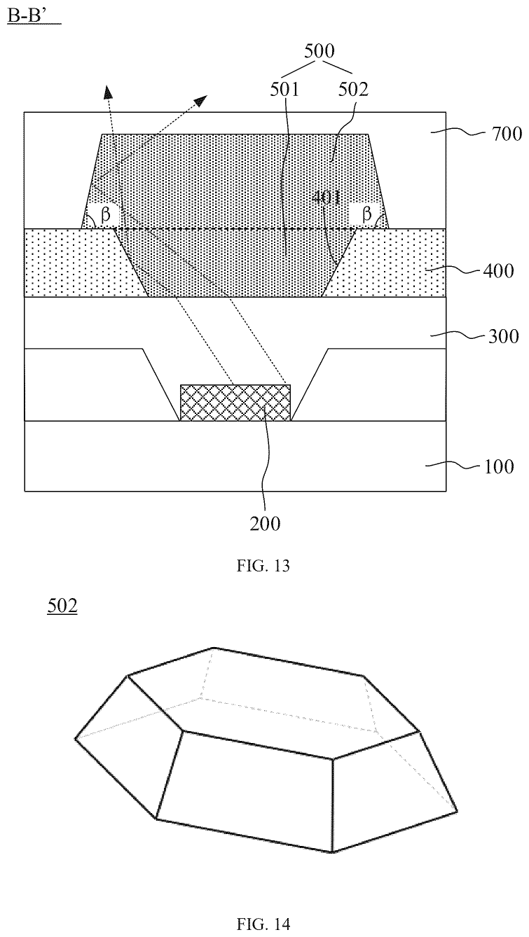

In a second optional implementation is shown in FIG. 11, FIG. 12, and FIG. 13, FIG. 11 is a top view of another display panel according to other embodiments of the present disclosure, FIG. 12 is a schematic diagram of a film structure of the display panel at position A-A′ shown in FIG. 11, and FIG. 13 is a schematic diagram of a film structure of the display panel at position B-B′ shown in FIG. 11. As the maximum width of the orthographic projection of the first light-emitting device 200 on the driver backplane 100 in the first direction X is greater than the maximum width of the orthographic projection of the first light-emitting device 200 on the driver backplane 100 in the second direction Y. Therefore, FIG. 11 can be a cross-sectional view of the first light-emitting device 200 in the long side direction, and FIG. 12 is a cross-sectional view of the first light-emitting device 200 in the short side direction.

The transparent filling portion 500 in the display panel 000 may include a main body portion 501 disposed within the dimming opening 401, and a protrusion portion 502 disposed outside the dimming opening 401. Here, the orthographic projection of the protrusion portion 502 in the transparent filling portion 500 on the driver backplane 100 covers the orthographic projection of the main body portion 501 on the driver backplane 100. In the transparent filling portion 500, the angle β between the side surface of the protrusion portion 502 and the surface of the protrusion portion 502 close to the main body portion 501 is less than or equal to 90°. That is, the side surface of the protrusion portion 502 can be a plane that is substantially perpendicular to the surface of the encapsulation layer 300 away from the driver backplane 100, or the side surface of the protrusion portion 502 can also be an inclined surface, and the angle between the inclined surface and the surface of the protrusion portion 502 close to the main body portion 501 is an acute angle.

In the present disclosure, the display panel 000 may further include a second planarization layer 700 disposed on a side of the transparent filling portion 500 away from the driver backplane, and the refractive index of the second planarization layer 700 is less than the refractive index of the transparent filling portion 500. For example, the second planarization layer 700 may be disposed on the side of the transparent filling portion 500 away from the driver backplane 100, and the orthographic projection of the transparent filling portion 500 on the driver backplane 100 and the orthographic projection of the functional layer 400 on the driver backplane 100 may both be disposed within the orthographic projection of the second planarization layer 700 on the driver backplane 100.

In this case, as the light with a large viewing angle emitted from a position in the light-emitting layer of the first light-emitting device 200 having a smaller horizontal distance from the dimming opening 401 can be directed to the inner wall of the dimming opening 401, and the light with large viewing angle emitted from a position having a larger horizontal distance from the dimming opening 401 may not be directly directed to the inner wall of the dimming opening 401, the light may be emitted from the portion 501 of the transparent filling portion 500 and directed to the side surface of the protrusion portion 502 of the transparent filling portion 500. As the refractive index of the transparent filling portion 500 is greater than the refractive index of the second planarization layer 700, the light with a larger viewing angle emitted from the first light-emitting device 200 and directed to the side surface of the protrusion portion 502 can be totally reflected by the side surface of the protrusion portion 502, and the reflected light to exit the transparent filling portion 500 has a smaller angle with the normal of the display panel. In this way, a portion of the light with a large viewing angle emitted from the first light-emitting device 200 can be reflected by the inner wall of the dimming opening 401, and another portion of the light can be reflected by the side surface of the protrusion portion 502 in the transparent filling portion 500. In this way, the brightness of the light with a large viewing angle in the light emitted from the first light-emitting device 200 can be further reduced.

In some embodiments, as shown in FIG. 11, the shape of the orthographic projection of the protrusion portion 502 in the transparent filling portion 500 on the driver backplane 100 is the same as the shape of the orthographic projection of the first light-emitting device 200 on the driver backplane 100. For example, in the case that the shape of the orthographic projection of the first light-emitting device 200 on the driver backplane 100 is a hexagon, the orthographic projection of the protrusion portion 502 on the driver backplane 100 is also a hexagon. In this way, it can be ensured that the light with a large viewing angle emitted from each side of the first light-emitting device 200 can be emitted to the corresponding side surface of the protrusion portion 502, such that the side surface of the protrusion portion 502 can better reflect the light with a large viewing angle emitted from the first light-emitting device 200.

In order to more clearly see the structure of the protrusion portion 502 in the transparent filling portion 500, referring to FIG. 12, FIG. 13, and FIG. 14. FIG. 14 is a schematic diagram of a three-dimensional structure of a protrusion portion according to some embodiments of the present disclosure. The angles β between each side surface of the protrusion portion 502 and the surface of the protrusion portion 502 close to the main body portion 501 are equal, and are greater than or equal to 50°. In this way, each side surface of the protrusion portion 502 can better reflect the light with a large viewing angle in the light emitted from the first light-emitting device 200.

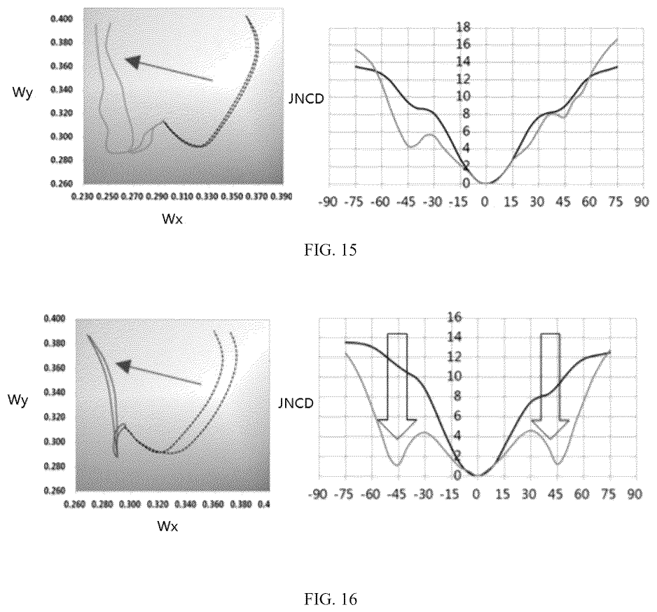

For example, referring to FIG. 15 and FIG. 16. FIG. 15 is another CIE trajectory comparison diagram and white light color deviation degree comparison diagram in a short side direction when a display panel provided by the present disclosure and a display panel in the related art present a white picture. FIG. 16 is another CIE trajectory comparison diagram and white light color deviation degree comparison diagram in a long side direction when a display panel provided by the present disclosure and a display panel in the related art present a white picture. The meaning of the coordinate system in FIG. 15 and FIG. 16 is the same as the meaning of the coordinate system in FIG. 9 and FIG. 10, and will not be repeated here. It can be seen from FIG. 15 and FIG. 16 that the picture presented by the display panel in the related art will be yellow at a large viewing angle, while the display panel in the present disclosure can effectively improve the phenomenon of picture luminescence at a large viewing angle. In addition, the display panel provided by the embodiments of the present disclosure has a white light large viewing angle color deviation (JNCD) value that is greatly reduced relative to the display panel in the related art, such that the color accuracy of the display panel provided by the embodiments of the present disclosure is higher.

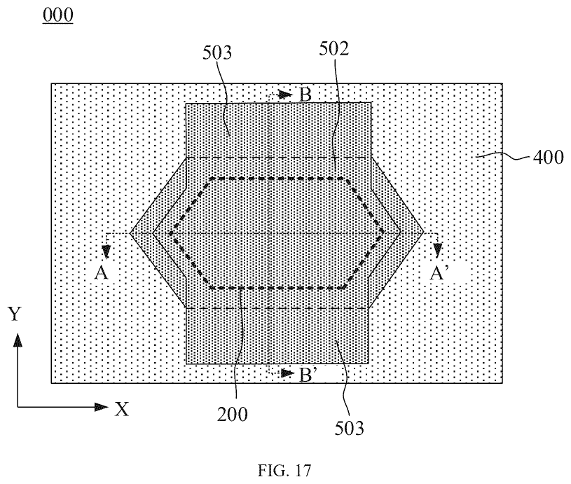

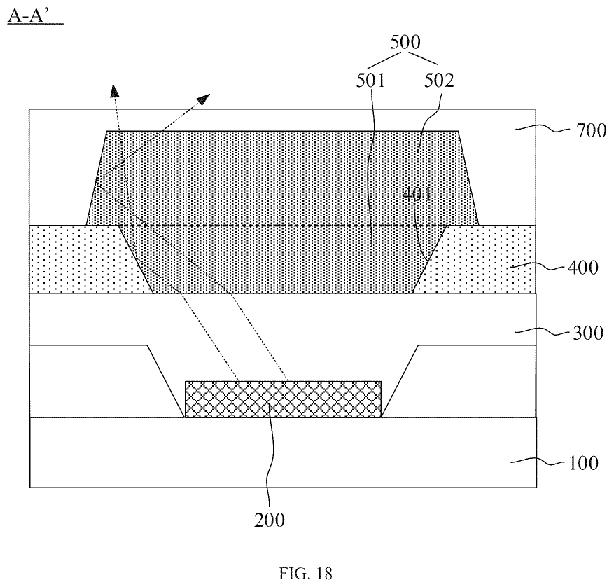

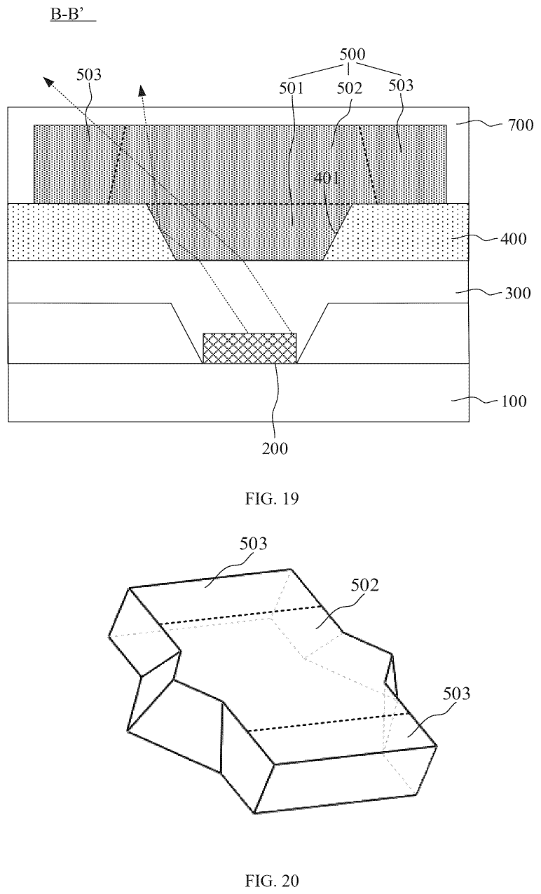

In a third optional implementation, as shown in FIG. 17, FIG. 18, and FIG. 19, FIG. 17 is a top view of another display panel according to other embodiments of the present disclosure, FIG. 18 is a schematic diagram of a film structure of the display panel at position A-A′ shown in FIG. 17, and FIG. 19 is a schematic diagram of a film structure of the display panel at position B-B′ shown in FIG. 17. As the maximum width of the orthographic projection of the first light-emitting device 200 on the driver backplane 100 in the first direction X is greater than the maximum width of the orthographic projection of the first light-emitting device 200 on the driver backplane 100 in the second direction Y. Therefore, FIG. 17 can be a cross-sectional view of the first light-emitting device 200 in the long side direction, and FIG. 18 is a cross-sectional view of the first light-emitting device 200 in the short side direction.

On the basis of the improved structure in the above-mentioned second optional implementation, the transparent filling portion 500 in the display panel 000 may further include an extension portion 503 disposed outside the dimming opening 401.

In order to more clearly see the structure of the extension portion 503 in the transparent filling portion 500, and the position between the extension portion 503 and the protrusion portion 502, referring to FIG. 20, FIG. 20 is a schematic diagram of a three-dimensional structure of a portion of a transparent filling portion disposed outside a dimming opening according to some embodiments of the present disclosure. The extension portion 503 in the transparent filling portion 500 can be arranged on both sides of the protrusion portion 502 in the second direction Y, and is fixedly connected to the side surface of the protrusion portion 502. For example, the main body portion 501, the protrusion portion 502, and the extension portion 503 in the transparent filling portion 500 may be an integral structure. For example, after forming the functional layer 400 with the dimming opening 401, a highly refractive transparent film may be formed on the side of the functional layer 400 away from the driver backplane 100, and then a patterning process is performed on the highly refractive transparent film to form the transparent filling portion 500 including the main body portion 501, the protrusion portion 502, and the extension portion 503.

It should be noted that the transparent filling portion 500 in the third optional implementation includes an extension portion 503, and the transparent filling portion 500 in the above-mentioned second optional implementation does not include an extension portion. As for other structures in the display panel (for example, the main body portion 501, the protrusion portion 502, and the second planarization layer 400 are all the same), for this reason, other structures in the display panel are not described again here.

In the present disclosure, the first optional implementation only uses the inner wall of the dimming opening 401 to reflect the light with a large viewing angle emitted from the first light-emitting device 200. This implementation can effectively reduce the brightness of the light with a large viewing angle emitted in the short side direction of the first light-emitting device 200, and as a portion of the light with a large viewing angle emitted in the long side direction of the first light-emitting device 200 cannot be directed to the inner wall of the dimming opening 200, this implementation has a low degree of reducing the brightness of the light with a large viewing angle emitted in the long side direction of the first light-emitting device 200.

The second optional implementation not only uses the inner wall of the dimming opening 401 to reflect the light with a large viewing angle emitted from the first light-emitting device 200, but also uses the side surface of the protrusion portion 502 to reflect the light with a large viewing angle emitted by the first light-emitting device 200. This implementation can effectively reduce the brightness of the light of a large viewing angle emitted in the long side direction of the first light-emitting device 200, but will result in an excessive reduction in the brightness of the light with a large viewing angle emitted in the short side direction of the first light-emitting device 200.

In the third optional implementation, as shown in FIG. 17, FIG. 18, and FIG. 19, as the transparent filling portion 500 includes the extension portions 503 distributed on both sides of the protrusion portion 502 in the second direction Y, and the maximum width d1 of the orthographic projection of the transparent filling portion 400 on the driver backplane 100 in the second direction Y is greater than or equal to the maximum width d2 in the first direction X. Therefore, in the light with a large viewing angle emitted from the first light-emitting device 200 in the short side direction, the light directed to the inner wall of the dimming opening 401 can be directly reflected by the inner wall of the dimming opening 401, while the light emitted from the main body portion 401 passes through the protrusion portion 502 and the extension portion 503 in sequence, and is emitted from the side of the extension portion 503 away from the driver backplane 100. For this reason, the light with a large viewing angle emitted from the first light-emitting device 200 in the short side direction that is emitted from the main body portion 401 will not be reflected by the side surface of the transparent filling portion 500 intersecting with the second planarization layer 700. In this way, it can be ensured that the brightness of the light with a large viewing angle emitted from the first light-emitting device 200 in the short side direction will not be reduced too much. In addition, in the light with a large viewing angle emitted from the first light-emitting device 200 in the long side direction, a portion of the light can still be reflected by the inner wall of the dimming opening 401, and another portion of the light can still be reflected by the side surface of the protrusion portion 502 in the transparent filling portion 500. In this way, the brightness of the light with a large viewing angle emitted by the first light-emitting device 200 in the long side direction can be effectively reduced. Therefore, in the third possible implementation, by providing the extension portions 503 on both sides of the protrusion portion 502, not only the brightness of the light with a large viewing angle emitted from the first light-emitting device 300 in the long side direction can be effectively reduced, but also the brightness of the light with a large viewing angle from by the first light-emitting device 200 in the short side direction can be ensured not to be reduced too much, such that the brightness of the display panel 000 at a large viewing angle can be ensured not to be too low under the premise that the picture presented by the display panel 000 at a large viewing angle does not appear yellowish.

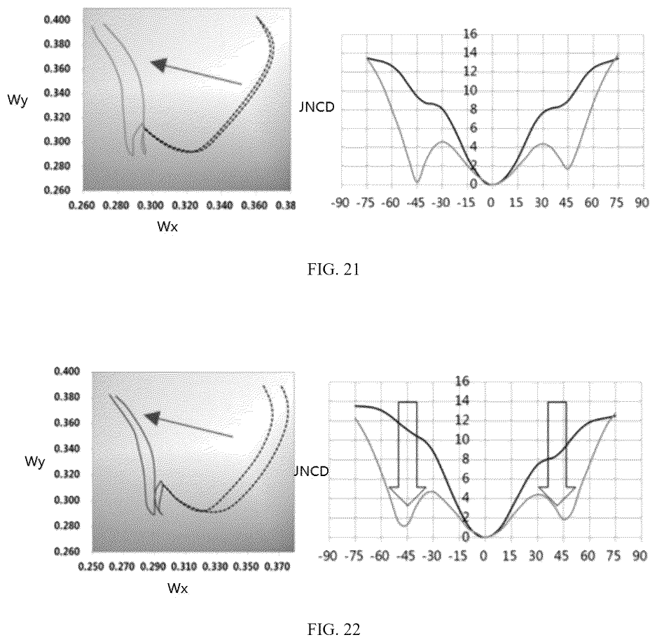

For example, referring to FIG. 21 and FIG. 22, FIG. 21 is another CIE trajectory comparison diagram and white light color deviation degree comparison diagram in a short side direction when a display panel provided by the present disclosure and a display panel in the related art present a white picture. FIG. 22 is another CIE trajectory comparison diagram and white light color deviation degree comparison diagram in a long side direction when a display panel provided by the present disclosure and a display panel in the related art present a white picture. The meaning of the coordinate system in FIG. 21 and FIG. 22 is the same as the meaning of the coordinate system in FIG. 9 and FIG. 10, and will not be repeated here. It can be seen from FIG. 21 and FIG. 22 that the picture presented by the display panel in the related art will be yellow at a large viewing angle, while the display panel in the present disclosure can effectively improve the phenomenon of picture luminescence at a large viewing angle. In addition, the display panel provided by the embodiments of the present disclosure has a white light large viewing angle color deviation (JNCD) value that is greatly reduced relative to the display panel in the related art, such that the color accuracy of the display panel provided by the embodiments of the present disclosure is higher.

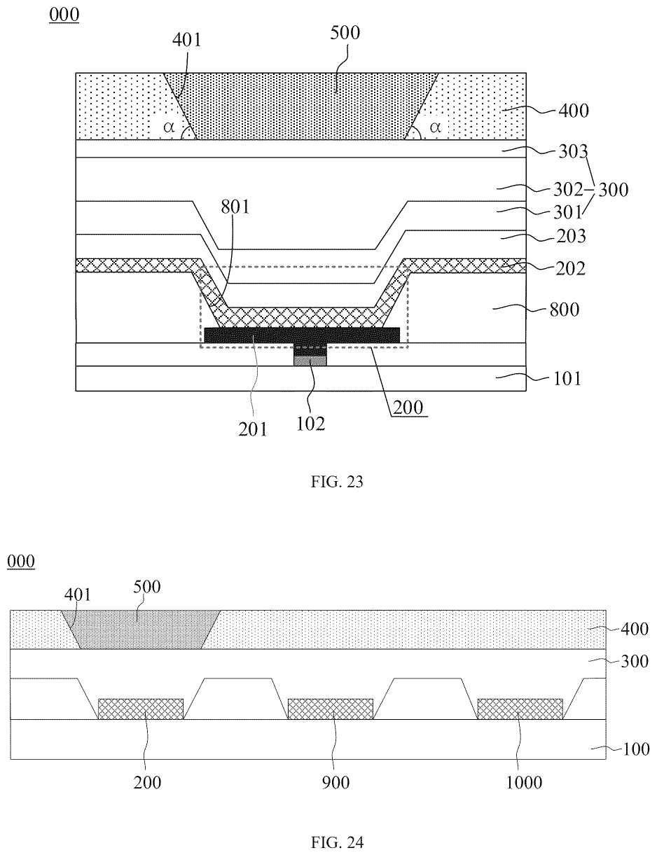

In some embodiments, as shown in FIG. 23, FIG. 23 is a schematic diagram of a film structure of a display panel according to yet other embodiments of the present disclosure. The refractive index of the encapsulation layer 300 in the display panel 000 is less than the refractive index of the transparent filling portion 500. In this way, it can be ensured that the light emitted from the first light-emitting device 200 that is transmitted from the encapsulation layer 300 and directed to the transparent filling portion 500 will not be totally reflected, thereby making the light extraction efficiency of the first light-emitting device 200 higher.

For example, the encapsulation layer 300 may include a first inorganic encapsulation layer 301, an organic encapsulation layer 302, and a second inorganic encapsulation layer 303 that are stacked. Here, the second inorganic encapsulation layer 303 is closer to the functional layer 400 than the first inorganic encapsulation layer 301. The refractive index of the transparent filling portion 500 in the display panel 000 may be greater than the refractive index of the second inorganic encapsulation layer 303.

In the embodiments of the present disclosure, the display panel 000 may include an anode layer, a pixel definition layer 800, a light-emitting layer 202, and a cathode layer 203 stacked and arranged on one side of the driver backplane 100. The pixel definition layer 800 has a plurality of light-emitting devices corresponding to a plurality of pixel openings 801. Here, the anode layer may include a plurality of anode blocks 201 corresponding to a plurality of pixel openings 801, and the orthographic projection of each anode block 201 on the driver backplane 100 may be disposed within the orthographic projection of the corresponding pixel opening 801 on the driver backplane 100. It should be noted that the anode block 201 corresponding to a certain pixel opening 801, the portion of the light-emitting layer 202 disposed within the pixel opening 801, and the portion of the cathode layer 203 disposed within the pixel opening 801 can constitute a light-emitting device corresponding to the pixel opening 801. The light-emitting device here may be a first light-emitting device 200 for emitting red light, a second light-emitting device for emitting green light, or a third light-emitting device for emitting blue light.

In some embodiments, the driver backplane 101 in the display panel 000 may include a substrate 101, and a plurality of pixel driving circuits 102 disposed on one side of the substrate 101. The plurality of pixel driving circuits 102 may be electrically connected to the plurality of light-emitting devices in the display panel 000 in a one-to-one correspondence. For example, each pixel driving circuit 102 may be electrically connected to an anode block 201 in a corresponding light-emitting device. Each pixel-driving circuit 102 is configured to drive the corresponding light-emitting device to emit light, and the plurality of pixel-driving circuits 101 are closer to the substrate 101 than the plurality of light-emitting devices.

In summary, the display panel provided by the embodiments of the present disclosure includes a driver backplane, a first light-emitting device, an encapsulation layer, a functional layer, and a transparent filling portion. The orthographic projection of the dimming opening of the functional layer on the driver backplane covers the orthographic projection of the first light-emitting device on the driver backplane, and the transparent filling portion with a higher refractive index can be distributed in the dimming opening. Therefore, the light emitted by the first light-emitting device can be directed to the transparent filling portion, and in the light entering the transparent filling portion, the light with a small viewing angle can be directly emitted after passing through the transparent filling portion, and the light with a large viewing angle can be directed to the inner wall of the dimming opening. Here, since the refractive index of the transparent filling portion is greater than the refractive index of the functional layer, the light with a large viewing angle in the light emitted by the first light-emitting device can be totally reflected by the inner wall of the dimming opening, such that the reflected light to exit the transparent filling portion has a smaller angle with the normal of the display panel, thereby reducing the brightness of the light with a large viewing angle in the light emitted by the first light-emitting device. In this way, even if the light-emitting layer in the first light-emitting device includes the TADF material, the probability of the display screen presented by the display panel at a large viewing angle being an overall yellowish can be effectively reduced, thereby making the display effect of the display panel better.

The embodiments of the present disclosure also provide a display device. The display device may be any product or component with a display function, such as a mobile phone, a tablet computer, a television, a monitor, a laptop computer, a digital photo frame, a navigator, and the like. The display device may include a power supply assembly and a display panel electrically connected to the power supply assembly. The display panel may be the display panel in the above embodiments.

It should be noted that in the accompanying drawings, the sizes of layers and regions may be exaggerated for clarity of illustration. It is also understood that when an element or layer is referred to as being “on” another element or layer, it may be directly on the other element, or there may be an intermediate layer. In addition, it is understood that when an element or layer is referred to as being “under” another element or layer, it may be directly under the other element, or there may be more than one intermediate layer or element. In addition, it is also understood that when a layer or element is referred to as being “between” two layers or two elements, it may be the only layer between the two layers or two elements, or there may also be more than one intermediate layer or element. Similar reference numerals throughout the text indicate similar elements.

In the present disclosure, the terms “first” and “second” are used for descriptive purposes only and should not be understood as indicating or implying relative importance. The term “a plurality of” refers to two or more than two, unless otherwise clearly defined.

The described above are merely optional embodiments of the present disclosure and are not intended to limit the present disclosure. Any modifications, equivalents, improvements, and the like, made within the spirit and principle of the present disclosure, should be included in the protection scope of the present disclosure.

1. A display panel, comprising:
a driver backplane;
a first light-emitting device disposed on a side of the driver backplane;
an encapsulation layer disposed on a side of the first light-emitting device away from the driver backplane;
a functional layer disposed on a side of the encapsulation layer away from the driver backplane, wherein the functional layer is provided with a dimming opening corresponding to the first light-emitting device, and an orthographic projection of the first light-emitting device on the driver backplane is disposed within an orthographic projection of the dimming opening on the driver backplane; and
a transparent filling portion at least partially disposed in the dimming opening, wherein a refractive index of the transparent filling portion is greater than a refractive index of the functional layer.

2. The display panel according to claim 1, wherein an angle between an inner wall of the dimming opening and a surface of the functional layer in contact with the encapsulation layer is less than or equal to 90°.

3. The display panel according to claim 2, wherein the angle between the inner wall of the dimming opening and the surface of the functional layer in contact with the encapsulation layer is greater than or equal to 50°.

4. The display panel according to claim 1, wherein a shape of an orthographic projection of the dimming opening on the driver backplane is a same as a shape of an orthographic projection of the first light-emitting device on the driver backplane.

5. The display panel according to claim 1, further comprising: a first planarization layer covering the functional layer, wherein a refractive index of the first planarization layer is greater than the refractive index of the functional layer, and a portion of the first planarization layer disposed in the dimming opening is the transparent filling portion.

6. The display panel according to claim 1, wherein the transparent filling portion comprises a main body portion disposed within the dimming opening, and a protrusion portion disposed outside the dimming opening, wherein an orthographic projection of the protrusion portion on the driver backplane covers an orthographic projection of the main body portion on the driver backplane, and an angle between a side surface of the protrusion portion and a surface of the protrusion portion close to the main body portion is less than or equal to 90°.

7. The display panel according to claim 6, wherein a shape of a surface of the protrusion portion facing away from the main body portion is a same as a shape of an orthographic projection of the first light-emitting device on the driver backplane.

8. The display panel according to claim 7, wherein angles between each side surface of the protrusion portion and a surface of the protrusion portion close to the main body portion are equal, and are greater than or equal to 50°.

9. The display panel according to claim 8, wherein the display panel comprises a plurality of the first light-emitting devices, the plurality of the first light-emitting devices are arranged in a plurality of columns along a first direction and in a plurality of rows along a second direction, and a maximum width of an orthographic projection of the first light-emitting device on the driver backplane in the first direction is greater than a maximum width of the orthographic projection of the first light-emitting device on the driver backplane in the second direction; and
the transparent filling portion further comprises an extension portion disposed outside the dimming opening, wherein the extension portion is arranged on both sides of the protrusion portion in the second direction, and is fixedly connected to the side surface of the protrusion portion.

10. The display panel according to claim 9, wherein a maximum width of an orthographic projection of the transparent filling portion on the driver backplane in the second direction is greater than or equal to a maximum width of the orthographic projection of the transparent filling portion on the driver backplane in the first direction.

11. The display panel according to claim 7, further comprising: a second planarization layer covering the transparent filling portion, wherein a refractive index of the second planarization layer is less than the refractive index of the transparent filling portion.

12. The display panel according to claim 1, wherein the refractive index of the transparent filling portion is greater than a refractive index of the encapsulation layer.

13. The display panel according to claim 1, wherein the first light-emitting device is a light-emitting device for emitting red light, and a light-emitting layer in the first light-emitting device comprises a thermally activated delayed fluorescence (TADF) material.

14. The display panel according to claim 13, further comprising: a second light-emitting device for emitting green light, and a third light-emitting device for emitting blue light, wherein the first light-emitting device, the second light-emitting device, and the third light-emitting device are arranged in a same layer; and
the orthographic projection of the dimming opening on the driver backplane is not overlapped with an orthographic projection of the second light-emitting device on the driver backplane, and is not overlapped with an orthographic projection of the third light-emitting device on the driver backplane.

15. A display device, comprising: a power supply assembly, and a display panel electrically connected to the power supply assembly, wherein the display panel comprises:
a driver backplane;
a first light-emitting device disposed on a side of the driver backplane;
an encapsulation layer disposed on a side of the first light-emitting device away from the driver backplane;
a functional layer disposed on a side of the encapsulation layer away from the driver backplane, wherein the functional layer is provided with a dimming opening corresponding to the first light-emitting device, and an orthographic projection of the first light-emitting device on the driver backplane is disposed within an orthographic projection of the dimming opening on the driver backplane; and
a transparent filling portion at least partially disposed in the dimming opening, wherein a refractive index of the transparent filling portion is greater than a refractive index of the functional layer.

16. The display device according to claim 15, wherein an angle between an inner wall of the dimming opening and a surface of the functional layer in contact with the encapsulation layer is less than or equal to 90°.

17. The display device according to claim 16, wherein the angle between the inner wall of the dimming opening and the surface of the functional layer in contact with the encapsulation layer is greater than or equal to 50°.

18. The display device according to claim 15, wherein a shape of an orthographic projection of the dimming opening on the driver backplane is a same as a shape of an orthographic projection of the first light-emitting device on the driver backplane.

19. The display device according to claim 15, further comprising: a first planarization layer covering the functional layer, wherein a refractive index of the first planarization layer is greater than the refractive index of the functional layer, and a portion of the first planarization layer disposed in the dimming opening is the transparent filling portion.

20. The display device according to claim 15, wherein the transparent filling portion comprises a main body portion disposed within the dimming opening, and a protrusion portion disposed outside the dimming opening, wherein an orthographic projection of the protrusion portion on the driver backplane covers an orthographic projection of the main body portion on the driver backplane, and an angle between a side surface of the protrusion portion and a surface of the protrusion portion close to the main body portion is less than or equal to 90°.
